(19) United States
(12) Patent Application Publication
(10) Pub. No.: US 2025/0038474 A1
(43) Pub. Date: Jan. 30, 2025

(54) OPTICAL SEMICONDUCTOR DEVICE

(71) Applicant: Mitsubishi Electric Corporation, Tokyo (JP)

(72) Inventors: Nobuyuki OGAWA, Tokyo (JP); Kazushige KAWASAKI, Tokyo (JP)

(73) Assignee: Mitsubishi Electric Corporation, Tokyo (JP)

(21) Appl. No.: 18/688,165

(22) PCT Filed: Nov. 8, 2021
(86) PCT No.: PCT/JP2021/040924

§ 371 Date: Feb. 29, 2024

(51) Int. Cl. H01S 5/028; H01S 5/042

(52) U.S. Cl. CPC H01S 5/028; H01S 5/04256

(57) ABSTRACT

An optical semiconductor device comprises: a semiconductor layer in which a resonator is formed; a reflective film covering both end faces of the semiconductor layer; an electrode pad formed by stacking metal layers; a support member arranged in each of positions on a mounting surface close to both the end faces, having a support face with a maximum height from the mounting surface and supporting a holder when the reflective film is coated; and a shield in which a portion higher than a bonding surface extends between each of sides of the mounting surface that are adjacent to both the end faces and the bonding surface so as to cover a region in which the bonding surface is formed in a left-right direction.

### TECHNICAL FIELD

The present application relates to an optical semiconductor device.

### BACKGROUND ART

In an optical semiconductor device, which is also referred to as a semiconductor laser element, it is necessary to reliably cover an end face with a reflective film. However, the coating wrapping around a surface other than the end face causes deterioration of the characteristics and an assembly failure. Although a length of a dummy bar or film formation conditions (such as the installation angle of the optical semiconductor device with respect to the coating source) are adjusted in order to suppress the wraparound of the coating, the wraparound cannot be completely suppressed due to the influence of various tolerances, and a certain number of wraparound failures occur on a daily basis.

In view of this, a technique has been proposed in which a groove is provided in one side or both sides of a dummy bar used at the time of the coating of the end face to suppress the coating from wrapping around a surface other than the end face (for example, refer to Patent Document 1).

### PRIOR ART DOCUMENT

### Non-Patent Document

Patent Document 1: Japanese Patent Application Laid-Open No. 2004-193257 (Paragraphs 0038 to 0039, FIG. 6 to FIG. 8)
Patent Document 2: Japanese Patent Application Laid-Open No. 2018-170308 (Paragraphs 0024 to 0025, FIG. 2A to FIG. 2C)

### SUMMARY OF INVENTION

### Problems to be Solved by Invention

However, in order to provide the groove in the dummy bar, it is necessary not only to simply cut out a base material for a dummy bar into a bar shape, but also to perform processing such as that for grooving the bar surface, which causes a significant increase in processing cost. Further, it is necessary to arrange bar of the optical semiconductor device in accordance with the groove of the dummy bar, and the degree of difficulty is very high as compared with a dummy bar having a normal shape even if the work is performed manually or automatically.

In addition, a technique has been proposed in which a resin layer having a recessed shape is formed as an under layer for an electrode pad, the electrode pad itself is formed in the recessed shape, and the coating is prevented from wrapping around the bonding surface of the electrode pad (for example, refer to Patent Document 2). However, in this case, it is difficult to control the recessed shape in the formation of the resin layer serving as the under layer, it is difficult to obtain reproducibility for each manufacturing lot, and the management of the result is likely to be complicated. That is, it has been difficult to suppress the wraparound of the coating with good reproducibility.

The present application discloses a technique for solving the above-described problems, and an object of the present application is to obtain an optical semiconductor device capable of preventing wraparound of coating with good reproducibility.

### Means for Solving Problems

An optical semiconductor device disclosed in the present application includes a semiconductor layer in which a plurality of crystal layers are stacked on a semiconductor substrate and a resonator extending in a direction perpendicular to a stacking direction is formed, a reflective film covering both end faces of the semiconductor layer in the extending direction of the resonator, an electrode pad that is locally formed by stacking metal layers on a mounting surface opposite to a surface on which a rear surface electrode is disposed among surfaces perpendicular to the stacking direction of the semiconductor layer so as to have a bonding surface to be connected to a bonding wire, and is for injecting a current into the semiconductor layer between the electrode pad and the rear surface electrode, a support member that is arranged at each of positions on the mounting surface close to both the end faces, has a flat surface having a maximum height from the mounting surface in the stacking direction, and supports a holder when the reflective film is coated, and a shielding mechanism in which a portion higher than the bonding surface in the stacking direction extends between each of sides of the mounting surface that are adjacent to both the end faces and the bonding surface so as to cover a region in which the bonding surface is formed in a direction perpendicular to the extending direction on the mounting surface.

### Advantageous Effect of Invention

According to the optical semiconductor device disclosed in the present application, since the support face capable of stably supporting the dummy bar and the shielding mechanism are formed, it is possible to obtain an optical semiconductor device capable of preventing the coating from wrapping around with good reproducibility.

### BRIEF DESCRIPTION OF THE DRAWINGS

FIG. 1 is a perspective view for describing a configuration of an optical semiconductor device according to Embodiment 1.

FIG. 2A to FIG. 2C are a plan view, a front view, and an end face view, respectively, for describing the configuration of the optical semiconductor device according to Embodiment 1.

FIG. 3A and FIG. 3B are a front view and an end face view, respectively, showing a state where a semiconductor bar before chip separation is sandwiched by dummy bars in a manufacturing process for applying an end face coating to the optical semiconductor device according to Embodiment 1.

FIG. 4 is a perspective view for describing a configuration of an optical semiconductor device according to Embodiment 2.

FIG. 5A to FIG. 5C are a plan view, a front view, and an end face view, respectively, for describing the configuration of the optical semiconductor device according to Embodiment 2.

FIG. 6A and FIG. 6B are a front view and an end face view, respectively, showing a state in which a semiconductor bar before chip separation is sandwiched by dummy bars in a manufacturing process for applying an end face coating to the optical semiconductor device according to Embodiment 2.

FIG. 7 is a perspective view for describing a configuration of an optical semiconductor device according to Embodiment 3.

FIG. 8A to FIG. 8C are a plan view, a front view, and an end face view, respectively, for describing the configuration of the optical semiconductor device according to Embodiment 3.

FIG. 9A and FIG. 9B are a front view and an end face view, respectively, showing a state in which a semiconductor bar before chip separation is sandwiched by dummy bars in a manufacturing process for applying an end face coating to the optical semiconductor device according to Embodiment 3.

FIG. 10 is a perspective view for describing a configuration of an optical semiconductor device according to Embodiment 4.

FIG. 11A to FIG. 11C are a plan view, a front view, and an end face view, respectively, for describing the configuration of the optical semiconductor device according to Embodiment 4.

FIG. 12A and FIG. 12B are a front view and an end face view, respectively, showing a state in which a semiconductor bar before chip separation is sandwiched by dummy bars in a manufacturing process for applying end face coating to the optical semiconductor device according to Embodiment 4.

### MODE FOR CARRYING OUT INVENTION

Hereinafter, embodiments of the present application will be described with reference to the drawings. In the drawings used in this specification, common elements are denoted by the same reference numerals, and redundant description thereof will be omitted.

### Embodiment 1

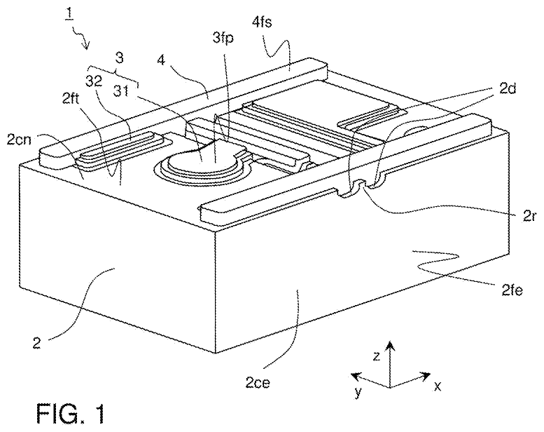

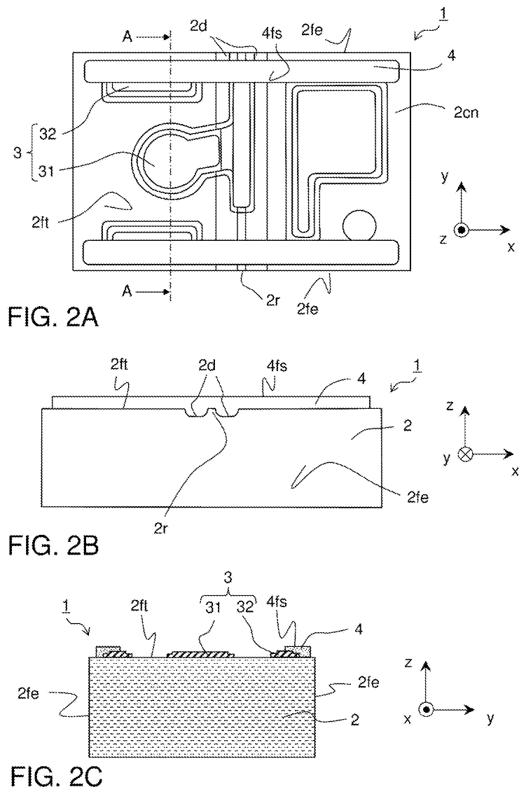

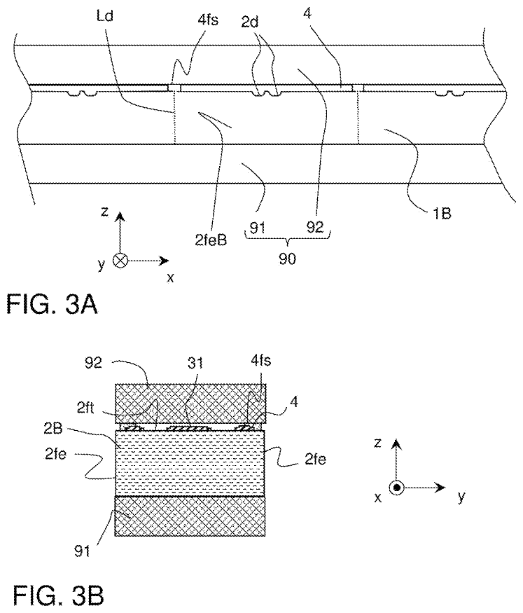

FIG. 1 to FIG. 3A, and FIG. 3B are diagrams for describing an optical semiconductor device and a method for manufacturing the optical semiconductor device according to Embodiment 1. FIG. 1 is a perspective view for describing a configuration of the optical semiconductor device, FIG. 2A is a plan view seen from the side of a mounting surface of the optical semiconductor device, FIG. 2B is a front view seen from an end face side of the optical semiconductor device, and FIG. 2C is an end face view taken along a line A-A of FIG. 2A. Further, FIG. 3A is a front view as viewed from the end face side showing a state in which a semiconductor bar before chip separation is sandwiched between dummy bars at upper and lower sides, and FIG. 3B is an end face view in that state, corresponding to FIG. 2C.

In the optical semiconductor device 1 according to Embodiment 1, as shown in FIG. 1 and FIG. 2A to FIG. 2C, a semiconductor layer 2 is formed by etching or the like, and members such as an electrical pad 31, etc. are provided. The semiconductor layer 2 is formed of a semiconductor substrate such as an indium phosphide (InP) substrate or a gallium arsenide (GaAs) substrate, and various crystal layers epitaxially grown thereon (in the z-direction) by metal organic chemical vapor deposition (MOCVD) or the like. Then, both ends in the y-direction are cut by cleavage to be described later, and both ends in the x-direction are cut by dicing, thereby forming a substantially rectangular parallelepiped shape.

Inside the semiconductor layer 2, a resonator 2r for emitting laser light is formed to extend in the y-direction in the figure, and both ends of the resonator 2r in the extending direction, i.e., light traveling direction, are cut by crystal cleavage or the like to be formed as end faces 2fe, and a reflective film 2ce is formed on the surfaces thereof. On both sides of the resonator 2r, grooves 2d of the semiconductive layer 2 is provided along the resonator 2r. A nitride film 2cn is formed on the outermost surface (mounting surface 2ft) of the semiconductor layer 2 to protect the surface of the semiconductor layer.

A rear surface electrode not denoted by a reference numeral is provided on the entire rear surface (lower surface in the figure) of the semiconductor layer 2. Further, a metal layer 3 is provided on the mounting surface 2ft opposite to the rear surface. The metal layer 3 includes an electrode pad 31 that is electrically connected to the resonator 2r and injects a current into the semiconductor layer 2 between itself and the rear surface electrode, and electrode patterns 32, etc. The metal layer 3 is made of a metal formed by a method such as sputtering, plating, or vapor deposition. As the metal, gold (Au), titanium (Ti), platinum (Pt), or a stacked structure thereof is used. The configuration described above is the same as that of a typical optical semiconductor device.

As a characteristic configuration of the optical semiconductor device 1 according to Embodiment 1, a support member 4 that is made of a resin having a flat support face 4fs with a maximum and constant height in the z-direction is formed in a region close to a side on the end face 2fe side on the mounting surface 2ft of the semiconductor layer 2 so as to extend along the end face 2fe. Polyimide, alkyd resin, or the like is used for the support member 4. Typically, since the metal used for the electrode pad 31 has a thickness of about 3 to 6 μm, the thickness of the support member 4 is set to about 6 to 10 μm, which is larger than the thickness of the metal.

The support member 4 is formed in the desired pattern after filling with coating, the grooves 2d in the semiconductor layer 2 and the unevenness of the mounting surface 2ft caused by the metal for forming the electrode pads 31 so as to obtain the thickness described above. The outermost surface of the support member 4, which serves as the support face 4fs, is finished into a flat shape and leveled. In order to obtain the thickness and a flat shape (flat support face 4fs), for the support member 4, a spin coating method is used for the coating.

On the premise of the above-described configuration, film formation (end face coating) of the reflective film 2ce will be described. As shown in FIG. 3A and FIG. 3B, a semiconductor bar 1B having a bar shape, in which dicing along dicing lines Ld for the separation of the chips is not performed, are subjected to the end face coating with dummy bars 91 and 92 (collectively, dummy bar 90) alternately arranged with respect to the semiconductor bar 1B.

Since the outermost surface of the support member 4 is the support face 4fs having the flat shape, only the support face 4fs comes into contact with the flat dummy bar 90 on the side of the mounting face 2ft. In addition, since the support member 4 (support face 4fs) is arranged in each of the front-back sides (y-direction) of the semiconductor bar 1B, the dummy bar 90 is not allowed to incline with respect to the semiconductor bar 1B.

Thus, the support face 4fs can be brought into close contact with the dummy bar 92 without a clearance. As a matter of course, since the bottom surface of the semiconductor bar 1B, which is not denoted by a reference numeral, is also flat, the semiconductor bar 1B can be brought into close contact with the dummy bar 91 without a clearance. Therefore, when the end face coating is performed, the support member 4 serves as a barrier, and it is possible to obtain an effect of preventing the coating from wrapping around the inner side (y-direction) of the support member 4 on the mounting surface 2ft.

The support member 4 is provided separately in the front-back direction (y-direction) at a distance from the electrode pad 31, and is provided at each of the positions closer to the edges than to the center in the front-back direction. Since the highest position (z-direction) of the semiconductor bar 1B corresponds to the flat support face 4fs distributed and arranged in the front-back direction by the support member 4 arranged in such a manner, the flat dummy bar 90 is brought into close contact without being inclined, and the wraparound of the coating can be reliably prevented.

Note that it is also considered that the support member is provided at a distance from the electrode pad 31, is separated in the left-right direction (x-direction), and is provided at positions closer to the edges than to the center in the left-right direction. However, since it is assumed that the end face coating is performed on the target as the semiconductor bar 1B before dicing, it does not necessarily need to distribute the support member in the left-right direction with respect to the function for preventing the inclination of the dummy bar 90.

In contrast, since the end face coating is performed after the end face 2fe is formed, it is important that the support portion (support face 4fs) for the dummy bar 90 is at positions distributed in the front-back direction and closer to both edges than to the center. On the other hand, as for the function for the barrier, it is desirable that the support member extends so as to cover at least the region of a bonding surface 3fp of the electrode pad 31 in the left-right direction. In particular, by the support member extending along each side of the mounting surface 2ft that is adjacent to the end face 2fe (at least in a range closer to both edges than to the center in the left-right direction), it is possible to more reliably prevent the wraparound of the coating. It is possible to form the support member up to both edges in the left-right direction, however, in consideration of handling and the like in the manufacturing process, a margin is provided at inner portions with respect to the edges.

### Embodiment 2

In Embodiment 1, the description has been given in the example in which the flat support face of the support member extends in the left-right direction in the region close to each of the two sides of the mounting surface on the end face side. In Embodiment 2, an example in which an electrode pad portion is opened and the support face is continuous in the front-back direction will be described.

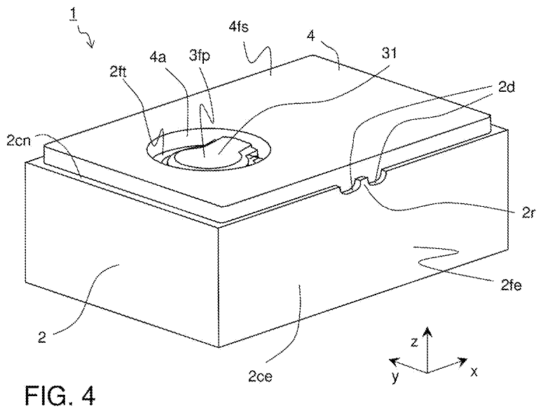

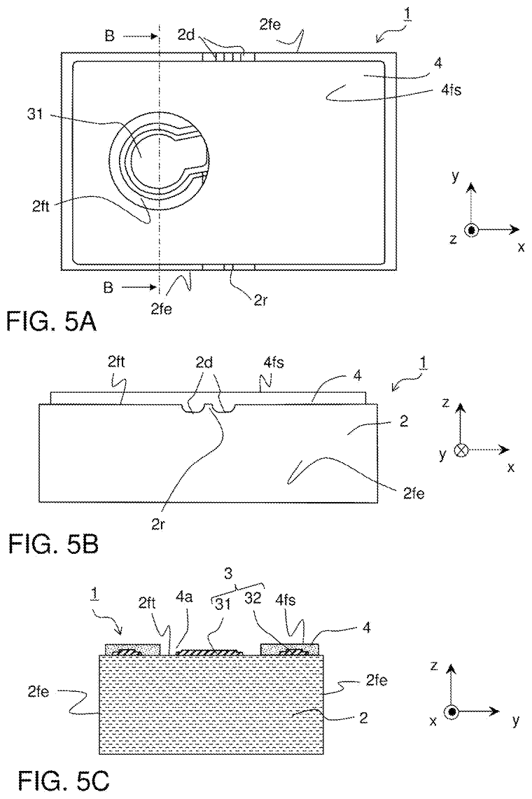

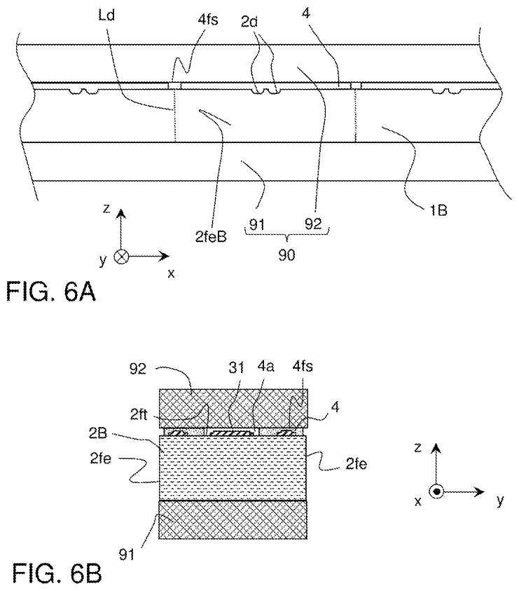

FIG. 4 to FIG. 6A and FIG. 6B are diagrams for describing an optical semiconductor device and a method for manufacturing the optical semiconductor device according to Embodiment 2. FIG. 4 is a perspective view for describing a configuration of the optical semiconductor device, FIG. 5A is a plan view of the optical semiconductor device as viewed from the side of the mounting surface, FIG. 5B is a front view of the optical semiconductor device as viewed from the end face side, and FIG. 5C is an end face view taken along a line B-B of FIG. 5A. Further, FIG. 6A is a front view as viewed from the end face side, showing a state in which a semiconductor bar before chip separation is sandwiched between dummy bars at upper and lower sides, and FIG. 6B is an end face view in that state, corresponding to FIG. 5C. The same parts as those in Embodiment 1 are denoted by the same reference numerals, and the descriptions thereof will be omitted.

As shown in FIG. 4, and FIG. 5A to FIG. 5C, the optical semiconductor device 1 according to Embodiment 2 is also configured such that the semiconductor layer 2 is formed by etching or the like, and members such as the electrode pad 31, etc. are provided as in Embodiment 1. The semiconductor layer 2 is formed of a semiconductor substrate such as an InP substrate or a GaAs substrate, and various crystal layers epitaxially grown thereon by a metal organic chemical vapor deposition method or the like, and has a substantially rectangular parallelepiped shape.

Both ends in the extending direction of a resonator 2r formed inside the semiconductor layer 2 are cut by crystal cleavage or the like and formed as the end faces 2fe, reflective films 2ce are formed on the surfaces, and both sides of the resonator 2r are provided with the grooves 2d of the semiconductor layer 2 in a shape along the resonator 2r. The nitride film 2cn is formed on the mounting surface 2ft of the semiconductor layer 2 to protect the surface of the semiconductor layer, and the electrode pad 31 electrically connected to the resonator 2r is provided. The configuration up to the point above are the same as that of a typical optical semiconductor device as in Embodiment 1.

As a characteristic configuration of the optical semiconductor device 1 according to Embodiment 2, the flat support face 4fs having the maximum and constant height in the z-direction is continuous from one end side to the other end side in the front-back direction (y-direction), which is the extending direction of the resonator 2r, except for the portion of the electrical pad 31. As in Embodiment 1, polyimide, alkyd resin, or the like is used for the support member 4.

The support member 4 is formed in the desired pattern after filling with coating, the grooves 2d in the semiconductor layer 2 and the unevenness of the mounting surface 2ft caused by the metal for forming the electrode pads 31 so as to obtain the thickness described above. The outermost surface of the support member 4, which serves as the support face 4fs, is finished into a flat shape and leveled. In order to obtain the thickness and a flat shape (flat support face 4fs), for the support member 4, a spin coating method is used for the coating.

Further, by providing an opening 4a for exposing the bonding surface 3fp, electrical connection by wire bonding is made possible. The opening 4a may be formed by patterning with a photoresist and dry etching after forming a film made of resin constituting the support member 4 on the entire surface of the mounting surface 2ft except for the peripheral portion, or may be opened by direct exposure if the support member 4 itself is photosensitive. Since the metal constituting the electrode pad 31 is typically 3 to 6 μm thick, the support member 4 is made thicker, i.e., about 6 to 10 μm, and the opening 4a is opened to have a size larger than the formation region of the electrode pad 31 by 5 to 10 μm.

On the premise of the above-described configuration, a description will be given for the end face coating targeting the semiconductor bar 1B of the optical semiconductor device 1 according to Embodiment 2. As shown in FIG. 6A and FIG. 6B, the semiconductor bar 1B before chip separation by dicing are subjected to the end face coating with the dummy bars 90 alternately arranged with respect to the semiconductor bar 1B.

Since the outermost surface of the support member 4 is the support face 4fs having the flat shape, only the support face 4fs comes into contact with the flat dummy bar 90 on the side of the mounting surface 2ft. Moreover, since the support member 4 (support face 4fs) extends in the left-right direction (x-direction) on each of the front-back sides (y-direction) of the semiconductor bar 1B, the dummy bar 90 is not inclined with respect to the semiconductor bar 1B.

Furthermore, in the optical semiconductor device 1 of Embodiment 2, the area covered by the support member 4 is larger than that in the optical semiconductor device 1 of Embodiment 1, and basically, the support face 4fs always exists in some area in the front-back direction. Therefore, even if the dummy bar 90 is displaced in the front-back direction, the support portion for the dummy bar 90 is always formed, and the dummy bar 90 is brought into close contact with the support face 4fs without being inclined. Therefore, it is possible to more reliably prevent the wraparound of the coating.

### Embodiment 3

In Embodiment 1 and Embodiment 2 described above, examples in which the support member made of resin is formed on the mounting surface have been described. In Embodiment 3, an example in which a support member is formed by electrode patterns formed simultaneously with the electrode pad will be described.

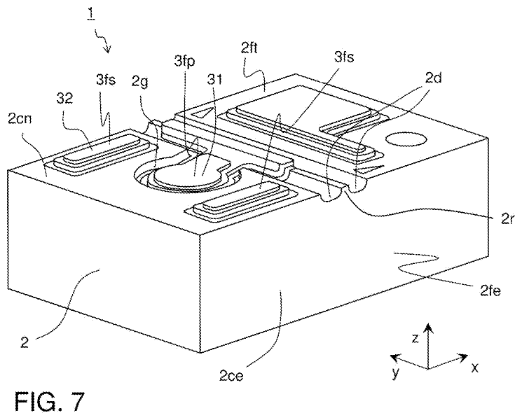

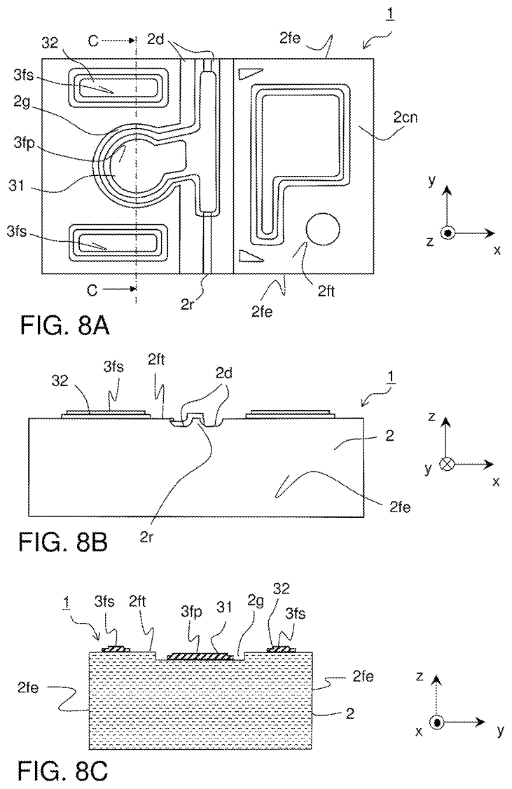

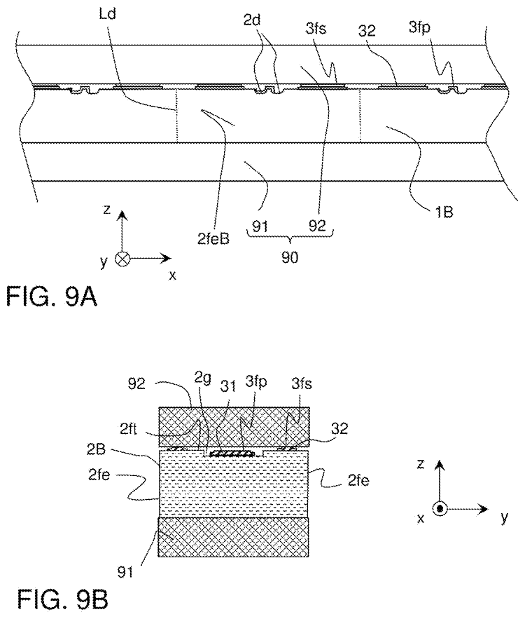

FIG. 7 to FIG. 9A and FIG. 9B are diagrams for describing an optical semiconductor device and a method for manufacturing the optical semiconductor device according to Embodiment 3. FIG. 7 is a perspective view for describing a configuration of the optical semiconductor device, FIG. 8A is a plan view of the optical semiconductor device as viewed from the side of the mounting surface, FIG. 8B is a front view of the optical semiconductor device as viewed from the end face side, and FIG. 8C is an end face view taken along a line C-C of FIG. 8A. Further, FIG. 9A is a front view as viewed from the end face side, showing a state in which a semiconductor bar before chip separation is sandwiched between dummy bars at upper and lower sides, and FIG. 9B is an end face view corresponding to FIG. 8C in that state. The same parts as those in Embodiment 1 or Embodiment 2 are denoted by the same reference numerals, and descriptions of the same parts will be omitted.

As shown in FIG. 7 and FIG. 8A to FIG. 8C, the optical semiconductor device 1 according to Embodiment 3 is also configured such that the semiconductor layer 2 is formed by etching or the like, and members such as the electrode pad 31, etc. are provided as in Embodiment 1. The semiconductor layer 2 is formed of a semiconductor substrate such as an InP substrate or a GaAs substrate, and various crystal layers epitaxially grown thereon by a metal organic chemical vapor deposition method or the like, and has a substantially rectangular parallelepiped shape.

As for the formation of the semiconductor layer 2, in addition to the grooves 2d formed along the resonator 2r on both sides of the resonator 2r, in Embodiment 3, a recess 2g is formed by recessing the region where the electrode pad 31 is to be formed. Then, the nitride film 2cn is formed on the mounting surface 2ft of the semiconductor layer 2, and the electrode pad 31 electrically connected to the resonator 2r is provided on the portion of the recess 2g, and at the same time, the electrode patterns 32 are provided on the other portions as in Embodiment 1 or Embodiment 2.

The height of the bonding surface 3fp located on the outermost surface of the electrode pad 31 is lower than the height of the outermost surface of the surrounding nitride film (mounting surface 2ft). Typically, the semiconductor layer 2 is recessed to a depth of about 6 μm or more in order to obtain electrical isolation. The recess of the semiconductor element 2, that is, the recess 2g, where the electrode pad 31 is to be provided, may be formed in the same process as the grooves 2d of the semiconductor element 2 at the sides of the resonator 2r, or may be formed in a different process in a case where the depth of the grooves 2d is insufficient. Regardless of the same process or a different process, the recess of the semiconductor layer 2 is formed by patterning of a photoresist and etching. The etching may be either dry or wet etching.

Thus, instead of the support member 4 of Embodiment 1 and Embodiment 2, the electrode patterns 32 have the highest surface (z-direction) in the optical semiconductor device 1 (support face 3fs). Since the metal layer 3 is formed by a method such as sputtering, plating, or vapor deposition, the metal layer 3 is finished to be flat and a leveled state without post-processing. As in Embodiment 1, the support face 3fs of the electrode pattern 32 is provided to be spaced apart from the electrode pad 31 in the front-back direction (y-direction), and is provided at each of the positions closer to the edges than to the center in the front-back direction.

On the premise of the above-described configuration, a description will be given for the end face coating targeting the semiconductor bar 1B of the optical semiconductor device 1 according to Embodiment 3. As shown in FIG. 9A and FIG. 9B, the semiconductor bar 1B before chip separation by dicing are subjected to the end face coating with the dummy bars 90 alternately arranged with respect to the semiconductor bar 1B.

Since the outermost surfaces of the electrode patterns 32 are the flat support faces 3fs, only the support faces 3fs are in contact with the flat dummy bar 90 on the side of the mounting surface 2ft. In addition, since the electrode pattern 32 (support face 3fs) is arranged in each of the front-back sides (in the y-direction) of the semiconductor bar 1B, the dummy bar 90 is not inclined with respect to the semiconductor bar 1B.

Further, the electrode pattern 32 is provided so as to be separated in the front-back direction (y-direction) at a distance from the electrode pad 31, and is provided at each of the positions closer to the edges than to the center in the front-back direction. Since the highest position (z-direction) of the semiconductor bar 1B corresponds to the flat support faces 3fs distributed and arranged in the front-back direction by the electrode patterns 32 arranged in such a manner, the flat dummy bar 90 is brought into close contact without being inclined, and the wraparound of the coating can be reliably prevented.

In addition, the metal (electrode patterns 32) other than the electrode pad 31 is formed on the surface where the semiconductor layer 2 is not recessed, and only the electrode pad 31 is formed in the portion where the semiconductor layer 2 is recessed. Therefore, the peripheral portion of the silicon layer 2 and the portion of the nitride film 2cn that surround the recess 2g and are higher than the bonding surface 3fp serve as a barrier against the coating agent entering the bonding surface 3fp of the electrode pad 31.

Furthermore, when the electrode patterns 32 formed in front-back sides to the electrode pad 31 extend so as to cover the region of the bonding surface of the electrode pad 31 in the left-right direction, it is possible to more reliably suppress the wraparound of the coating.

In the optical semiconductor device 1 according to Embodiment 3, it is not necessary to use an extra material such as the resin for the support member 4. In addition, if the recess 2g is formed in the same process as the grooves 2d, the number of processes does not increase, which is advantageous in terms of manufacturing cost.

### Embodiment 4

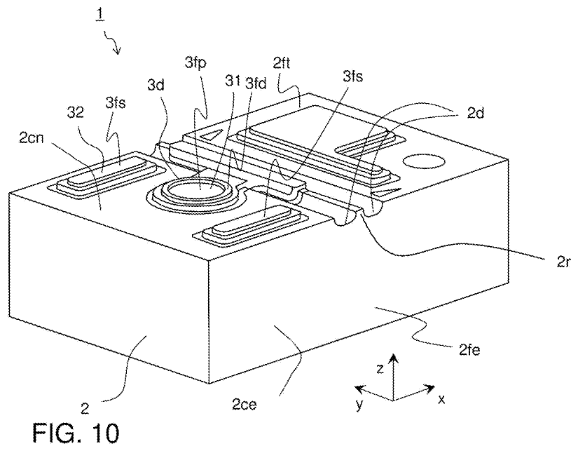

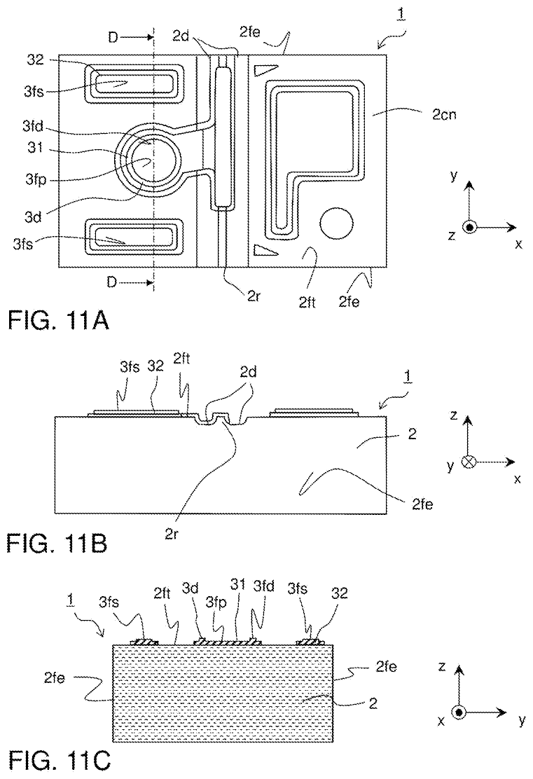

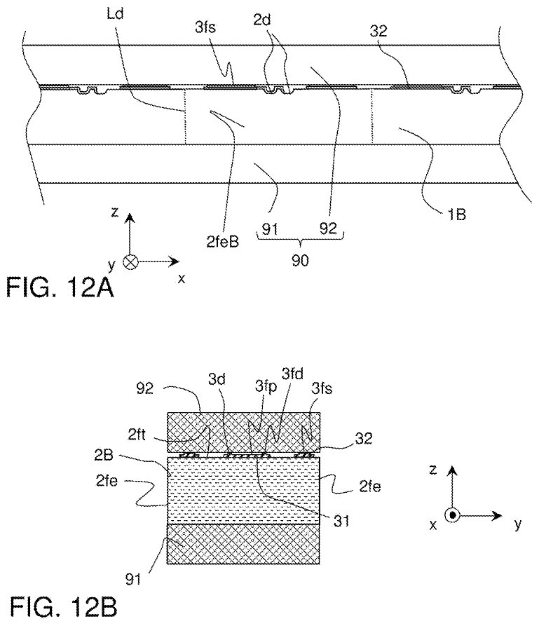

In Embodiment 4, an example in which a bank is provided in an electrode pad itself will be described. FIG. 10 to FIG. 12A and FIG. 12B are diagrams for describing an optical semiconductor device and a method for manufacturing the optical semiconductor device according to Embodiment 4. FIG. 10 is a perspective view for describing a configuration of the optical semiconductor device, FIG. 11A is a plan view of the optical semiconductor device as viewed from the side of the mounting surface, FIG. 11B is a front view of the optical semiconductor device as viewed from the end face side, and FIG. 11C is an end face view taken along a line D-D of FIG. 11A. Further, FIG. 12A is a front view as viewed from the end face side, showing a state in which the semiconductor bar before chip separation is sandwiched between dummy bars at upper and lower sides, and FIG. 12B is an end face view corresponding to FIG. 11C in that state. Note that the same parts as those in Embodiment 1 to Embodiment 3 are denoted by the same reference numerals, and descriptions of the same parts will be omitted.

As shown in FIG. 10 and FIG. 11A to FIG. 11C, in the optical semiconductor device 1 according to Embodiment 4, the semiconductor layer 2 is formed by etching or the like, and members such as the electrode pad 31, etc. are provided as in each of the embodiments described above. The semiconductor layer 2 is formed of a semiconductor substrate such as an InP substrate or a GaAs substrate, and various crystal layers epitaxially grown thereon by a metal organic chemical vapor deposition method or the like, and has a substantially rectangular parallelepiped shape.

Both ends in the extending direction of the resonator 2r formed inside the semiconductor layer 2 are cut by crystal cleavage or the like and formed as the end faces 2fe, the reflective films 2ce are formed on the surfaces, and both sides of the resonator 2r are provided with the grooves 2d of the semiconductor layer 2 in a shape along the resonator 2r. The nitride film 2cn is formed on the mounting face 2ft of the semiconductor layer 2 to protect the semiconductor layer 2.

As a characteristic configuration of the optical semiconductor device 1 according to Embodiment 4, the optical semiconductor device 1 is characterized in that the electrode pad 31 electrically connected to the resonator 2r is formed to have a bank 3d in which the periphery of the bonding surface 3fp is high. The bank 3d can be formed, for example, by using a plurality of kinds of patterns such that the bonding surface 3fp is masked in the middle of forming a plurality of metal layers 3, and the bank 3d and the electrode patterns 32 are finished to have the same height higher than the bonding surface 3fp.

Thus, as in Embodiment 3, the electrode patterns 32 and the bank 3d have the highest (z-direction) surfaces (the support face 3fs and a contact face 3fd) in the optical semiconductor device 1. Since the metal layer 3 is formed by a method such as sputtering, plating, or vapor deposition, the metal layer 3 is finished to be flat and a leveled state without post-processing. Further, as in Embodiment 1, the support face 3fs of the electrode pattern 32 is provided to be spaced apart from the electrode pad 31 in the front-back direction (y-direction), and is provided at each of the positions closer to the edges than to the center in the front-back direction.

On the premise of the above-described configuration, a description will be given for the end face coating targeting the semiconductor bar 1B of the optical semiconductor device 1 according to Embodiment 4. As shown in FIG. 12A and FIG. 12B, the semiconductor bar 1B before chip separation by dicing are subjected to the end face coating with the dummy bars 90 alternately arranged with respect to the semiconductor bar 1B.

Since the outermost surfaces of the electrode patterns 32 are the flat support faces 3fs and the flat contact face 3fd, only the support faces 3fs and the contact face 3fd are in contact with the flat dummy bar 90 on the side of the mounting surface 2ft. In addition, since the support face 3fs of the electrode pattern 32 is arranged in each of the front-back sides (y-direction) of the semiconductor bar 1B, the dummy bar 90 is not allowed to incline with respect to the semiconductor bar 1B.

Further, the electrode pattern 32 is provided so as to be separated in the front-back direction (y-direction) at a distance from the electrode pad 31, and is provided at each of the positions closer to the edges than to the center in the front-back direction. Since the dummy bar 90 is supported by the flat support faces 3fs of the electrode patterns 32 arranged in such a manner, the flat dummy bar 90 is not inclined, and thus the contact face 3fd, which is annular, and the dummy bar 90 are reliably brought into close contact with each other.

On the other hand, since the bonding surface 3fp of the electrode pad 31 is located inside the bank 3d, the bonding surface 3fp is covered with the inner circumferential surface of the bank 3d and the dummy bar 90 when the end face is coated. As a result, it is possible to reliably prevent the coating from wrapping around the bonding surface 3fp of the electrode pad 31.

In the optical semiconductor device 1 according to Embodiment 4, it is not necessary to use an extra material such as the resin for the support member 4. Further, as for the bank 3d, it is only necessary to mask the bonding surface 3fp in any of a plurality of patterns used in the step of forming the metal layers 3, and the number of processes does not increase, which is advantageous in terms of manufacturing cost.

In particular, since the electrode pad having the bank 3d is formed only by the metal layer 3, the height of the electrode pad can be accurately aligned with the height of the electrode patterns 32 without an additional process for adjusting the height, unlike the case where the recessed resin layer is formed as the under layer in Patent Document 2. Therefore, it does not cause such a problem that, for example, the dummy bar 90 is supported only by the bank, thereby causing an inclination, or a clearance is created between the bank and the dummy bar 90, thereby reducing the shielding function.

Further, although various exemplary embodiments and examples are described in the present application, various features, aspects, and functions described in one or more embodiments are not inherent in an application of the contents disclosed in a particular embodiment, and can be applicable alone or in their various combinations to each embodiment. Accordingly, countless variations that are not illustrated are envisaged within the scope of the art disclosed herein. For example, the case where at least one component is modified, added or omitted, and the case where at least one component is extracted and combined with a component disclosed in another embodiment are included.

As described above, the optical semiconductor device 1 of the present application includes the semiconductor layer 2 in which a plurality of crystal layers are stacked on a semiconductor substrate and the resonator 2r extending in the direction perpendicular to the stacking direction (z-direction) is formed, the reflective film 2ce covering both the end faces 2fe of the semiconductor layer 2 in the extending direction (y-direction) of the resonator 2r, the electrode pad 31 that is locally formed by stacking metal layers on the mounting surface 2ft opposite to the surface on which a rear surface electrode is disposed among the surfaces perpendicular to the stacking direction of the semiconductor layer 2 so as to have the bonding surface 3fp to be connected to a bonding wire, and is for injecting a current into the semiconductor layer 2 between the electrode pad 31 and the rear surface electrode, the electrode pad 31 that is formed by stacking the metal layers on the side of the mounting surface 2ft close to the resonator 2r among the surfaces perpendicular to the stacking direction of the semiconductor layer 2, is electrically connected to the resonator 2r, and has the bonding surface 3fp to be connected to a bonding wire, the support member 4 (electrode patterns 32 function as the support member) that is arranged at each of positions on the mounting surface (2ft) close to both the end faces (2fe), has the flat surface (support face 3fs, support face 4fs) having a maximum height from the mounting surface 2ft in the stacking direction, and supports a holder (dummy bar 90) when the reflective film 2ce is coated, and the shielding mechanism (support member 4, electrode patterns 32, mounting surface 2ft surrounding recess 2g, bank 3d) that prevents a coating agent from entering into the bonding surface 3fp when the reflective film 2ce is coated, by extending a portion higher than the bonding surface 3fp in the stacking direction between each of sides of the mounting surface 2ft that are adjacent to both the end faces 2fe and the bonding surface 3fp so as to cover a region in which the bonding surface 3fp is formed in the direction (x-direction) perpendicular to the extending direction on the mounting surface 2ft. For the reason above, the dummy bar 90 can be stably supported during the coating, and the wraparound of the coating can be prevented with good reproducibility.

In particular, when the support member 4 (or electrode patterns 32 that functions as support member) functions as the shielding mechanism, it is possible to reliably prevent the coating from wrapping around without increasing an installation area.

When the support member 4 is made of resin, the support member can be formed in a desired pattern on the mounting surface 2ft and the height of the support member can be easily adjusted.

In this case, the flat surface (support face 4fs) extends along each of the sides of the mounting surface 2ft that are adjacent to both the end faces 2fe, so that the flat surface can be stably support the dummy bar 90 and can also function as the shielding mechanism reliably.

Furthermore, when the support member 4 is configured such that it has an opening 4a where the bonding surface 3fp is exposed and the flat surface (support face 4fs) is continuous from one end side to the other end side in the extending direction (y-direction), the dummy bar 90 can be reliably supported even if there is misalignment in the extending direction (y-direction) between the support member and the dummy bar 90.

Alternatively, when the support member is constituted with the electrode pattern 32 formed in the same stacked structure (metal layer 3) as the electrode pad 31, the flat surface (support face 3fs) having a uniform height from the mounting surface 2ft can be reliably formed.

When the electrode pad 31 configured to be arranged inside the recess 2g formed by recessing the semiconductor layer 2 in the stacking direction (z-direction), and the portion of the semiconductor layer 2 surrounding the recess functions as the shielding mechanism, it is not necessary to use an extra material such as the resin for the support member 4. And when the recess 2g is formed in the same process as in the grooves 2d along the resonator 2r, the number of processes does not increase, which is advantageous in terms of manufacturing cost.

Alternatively, when the electrode pad 31 is formed to include the bank 3d that surrounds the bonding surface 3fp and serves as the shielding mechanism, the shielding mechanism can be formed by preparing for some mask patterns without extra processes.

### DESCRIPTION OF REFERENCE NUMERALS AND SIGNS

1: Optical semiconductor device, 2: semiconductor layer, 2ce: reflective film, 2cn: nitride film, 2d: groove, 2fe: end face, 2ft: mounting surface, 2g: recess, 2r: resonator, 3: metal layer, 31: electrode pad, 32: electrode pattern (support member), 3d: bank, 3fp: bonding surface, 3fs: support face, 4: support member, 4a: opening, 4fs: support face.

1-8. (canceled)

9. An optical semiconductor device comprising:
a semiconductor layer in which a plurality of crystal layers are stacked on a semiconductor substrate and a resonator extending in a direction perpendicular to a stacking direction is formed;
a reflective film covering both end faces of the semiconductor layer in the extending direction of the resonator;
an electrode pad that is locally formed by stacking metal layers on a mounting surface opposite to a surface on which a rear surface electrode is disposed among surfaces perpendicular to the stacking direction of the semiconductor layer so as to have a bonding surface to be connected to a bonding wire, and is for injecting a current into the semiconductor layer between the electrode pad and the rear surface electrode;
a support member that is arranged at each of positions on the mounting surface close to both the end faces, has a flat surface having a maximum height from the mounting surface in the stacking direction, and supports a holder when the reflective film is coated; and
a shield in which a portion higher than the bonding surface in the stacking direction extends between each of sides of the mounting surface that are adjacent to both the end faces and the bonding surface so as to cover a region in which the bonding surface is formed in a direction perpendicular to the extending direction on the mounting surface,
wherein
the support member is made of resin and has an opening in which the bonding surface is exposed, the flat surface extends along each of sides of the mounting surface that are adjacent to both the end faces, and the flat surface is continuous from one end side to the other end side in the extending direction.

10. The optical semiconductor device according to claim 9, wherein the support member functions as the shield.

11. An optical semiconductor device comprising:
a semiconductor layer in which a plurality of crystal layers are stacked on a semiconductor substrate and a resonator extending in a direction perpendicular to a stacking direction is formed;
a reflective film covering both end faces of the semiconductor layer in the extending direction of the resonator;
an electrode pad that is locally formed by stacking metal layers on a mounting surface opposite to a surface on which a rear surface electrode is disposed among surfaces perpendicular to the stacking direction of the semiconductor layer so as to have a bonding surface to be connected to a bonding wire, and is for injecting a current into the semiconductor layer between the electrode pad and the rear surface electrode;
a support member that is arranged at each of positions on the mounting surface close to both the end faces, has a flat surface having a maximum height from the mounting surface in the stacking direction, and supports a holder when the reflective film is coated; and
a shielding mechanism in which a portion higher than the bonding surface in the stacking direction extends between each of sides of the mounting surface that are adjacent to both the end faces and the bonding surface so as to cover a region in which the bonding surface is formed in a direction perpendicular to the extending direction on the mounting surface, wherein the support member is constituted with an electrode pattern formed in a stacked structure as with the electrode pad.

12. The optical semiconductor device according to claim 11, wherein the support member functions as the shield.

13. The optical semiconductor device according to claim 10, wherein the electrode pad is arranged inside a recess formed by recessing the semiconductor layer in the stacking direction, and a portion of the semiconductor layer surrounding the recess functions as the shield.

14. The optical semiconductor device according to claim 11, wherein the electrode pad is arranged inside a recess formed by recessing the semiconductor layer in the stacking direction, and a portion of the semiconductor layer surrounding the recess functions as the shield.

15. The optical semiconductor device according to claim 11, wherein a bank that surrounds the bonding surface and functions as the shield is formed in the electrode pad.

16. The optical semiconductor device according to claim 12, wherein a bank that surrounds the bonding surface and functions as the shield is formed in the electrode pad.

17. The optical semiconductor device according to claim 13, wherein a bank that surrounds the bonding surface and functions as the shield is formed in the electrode pad.

18. The optical semiconductor device according to claim 14, wherein a bank that surrounds the bonding surface and functions as the shield is formed in the electrode pad.
